(19) United States
(12) Patent Application Publication
(10) Pub. No.: US 2026/0241665 A1
(43) Pub. Date: Aug. 20, 2026

(54) COMPOSITE FILM, AND PREPARATION METHOD AND USE THEREOF

(71) Applicant: The Hong Kong University of Science and Technology (Guangzhou), Guangzhou (CN)

(72) Inventors: Suihua He, Guangzhou (CN); Ping Gao, Guangzhou (CN); Qi’ao Gu, Guangzhou (CN); Xin Ma, Guangzhou (CN)

(21) Appl. No.: 19/266,205

(22) Filed: Jul. 11, 2025

(30) Foreign Application Priority Data
Feb. 17, 2025 (CN) 202510170179.3
Mar. 13, 2025 (CN) 202510299144.X

(51) Int. Cl. B32B 5/26; B32B 5/02; H05K 1/02

(52) U.S. Cl. CPC B32B 5/26; B32B 5/02; H05K 1/028; B32B 2250/02; B32B 2250/20; B32B 2255/02; B32B 2255/205; B32B 2262/0253; B32B 2262/0269; B32B 2305/026; B32B 2307/202; B32B 2307/7376; B32B 2457/00

(57) ABSTRACT

Provided is a composite film, comprising a porous film, an aramid nanofiber layer and a rigid coating arranged in sequence. In the composite film of the present disclosure, the aramid nanofiber layer is an intermediate layer between the rigid coating and the flexible porous film and provides a mechanical transition therebetween and thus regulate interfaces thereof, so that a stable interface structure is achieved between the flexible porous film and the rigid coating, thereby effectively solving the delamination issue between the rigid coating and the flexible porous film.

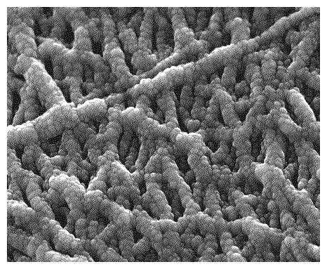

### CROSS-REFERENCE TO RELATED APPLICATION

The present application claims priority from Chinese Patent Application Nos. 202510170179.3, filed on Feb. 17, 2025, and 202510299144.X, filed on Mar. 13, 2025, the contents of which are incorporated herein by reference in their entireties.

### TECHNICAL FIELD

The present disclosure relates to the technical field of composite films, in particular to a composite film, and a preparation method and a use thereof.

### BACKGROUND

With the rapid development of electronic technology, devices having significant advantages such as lightweight, bendability and durability have gradually become important development directions in the electronics industry, attracting much attention. In cutting-edge fields such as wearable technology, electronic displays and smart sensors, such devices have shown great application potential and broad development prospects. However, current flexible electronic devices mainly rely on expensive and complex material systems such as polyimide and conductive polymers, which seriously restricts their large-scale commercialization. Since polyolefin materials have excellent mechanical properties, good chemical stability and significant cost-effectiveness, they are ideal materials for flexible electronic devices. However, using polyolefin materials in flexible electronic applications still have many challenges, which are mainly manifested in poor thermal stability and insufficient interfacial bonding with other functional coatings. Such problems seriously hinder their widespread applications in the field of flexible electronics.

Poly(p-phenylene terephthalamide) (PPTA), also known as para-aramid fiber (Kevlar), was originally developed and produced by DuPont de Nemours, Inc. in the United States in the 1960s and 1970s. PPTA is a rigid liquid crystal polymer with excellent thermal stability and mechanical properties. For example, it had been widely reported in Chinese patents CN104993089A and CN107452921A that PPTA was adopted to improve heat resistance of polyolefin-based diaphragms for lithium batteries. However, there has been no report on a method of achieving a firm interface structure between a rigid coating and a flexible film, by using PPTA as an intermediate layer. In addition, in Chinese patent application No. 201510453815.X and Japanese patent application JP-A-2010-254731, a para-aramid coating technology is proposed, where additional adhesives are required to be added to achieve the interface bonding between the aramid and polyolefin composite films. As reported in Chinese patent CN111883777A, plasma cleaning is necessary to ensure that a metal coating has sufficient adhesion to a substrate.

Therefore, enhancing the performance of polyolefin materials to better satisfy the requirements of flexible electronic devices has become a critical issue that needs to be solved in the current technical field. In view of this, this application is proposed.

### SUMMARY OF THE DISCLOSURE

An objective of the present disclosure is to provide a composite film, and a preparation method and a use thereof.

The present disclosure provides the following technical solution. The present disclosure provides a composite film, comprising a porous film, an aramid nanofiber layer and a rigid coating arranged in sequence; wherein the porous film is formed by a polyolefin nanofiber and has a porous structure; the aramid nanofiber layer is formed by an aramid nanofiber and has a porous structure; and the rigid coating is formed by at least one selected from the group consisting of copper, aluminum, platinum, gold, silver, titanium, molybdenum, silicon, aluminum oxide, indium tin oxide, silicon oxide and titanium oxide.

In some embodiments, the porous film has a thickness of 0.1-10 μm, a pore size of 20-80 nm and a porosity of 30-60%; a diameter of the polyolefin nanofiber is 30-60 nm; and/or
the aramid nanofiber layer has a thickness of ≥0.05 μm, a pore size of 20-80 nm and a porosity of 10-50%; a diameter of the aramid nanofiber is 10-50 nm.

In some embodiments, a thickness of the rigid coating is 0.01-1 μm.

In some embodiments, the pore size of the porous film is 30-40 nm, and the porosity of the porous film is 35-50%; the diameter of the polyolefin nanofiber is 45-55 nm.

In some embodiments, the pore size of the aramid nanofiber layer is 30-50 nm, and the porosity of the aramid nanofiber layer is 30-40%; the diameter of the aramid nanofiber is 20-30 nm.

In the present disclosure, the deprotonation-reprotonation process of the aramid fiber is utilized to establish the entanglement, along with the nano-confinement effect, between the aramid nanofiber layer and the flexible porous film, thereby addressing the issue that the addition of an adhesive or a surface treatment is required to achieve the interfacial bonding between the aramid nanofiber and the porous film in the prior art. In the composite film of the present disclosure, the aramid nanofiber layer is an intermediate layer between the rigid coating and the flexible porous film and provides a mechanical transition therebetween and thus regulate interfaces thereof, so that a stable interface structure is achieved between the flexible porous film and the rigid coating, thereby effectively solving the delamination issue between the rigid coating and the flexible porous film.

In some embodiments, the thickness of the porous film is 2-5 μm; and/or the thickness of the aramid nanofiber layer is 0.2-1 μm; and/or the thickness of the rigid coating is 0.05-0.5 μm.

In some embodiments, the thickness of the porous film is 2.5-4 μm.

In some embodiments, the polyolefin is polypropylene and/or polyethylene. In some embodiments, the polyolefin is polyethylene.

In some embodiments, the porous film may be commercially available or homemade. Specifically, the porous film can be prepared by wet or dry stretching methods.

In some embodiments, a preparation method of the porous film comprises the following steps: adding a polyolefin-based polymer and a lubricant to a twin-screw extruder, blending and extruding a gel sheet, then stretching the gel sheet into a ultra-thin film through a biaxial stretching process, and finally subjecting the ultra-thin film to extraction and annealing to obtain an ultra-thin nanoporous polyolefin-based film, which is formed by a polyolefin nanofiber and has a porous structure, i.e., the porous film. In some embodiments, a stretching ratio of the gel sheet during the biaxial stretching process is (5-20)×(5-20).

In some embodiments, an original thickness of the prepared porous film is (0.1-5)±0.5 μm.

In some embodiments, the present disclosure also provides a preparation method of the composite film, comprising the following steps:
S1, evenly mixing an aramid fiber, an alkaline solution and an organic solvent to obtain an aramid nanofiber dispersion;
S2, coating a surface of the porous film with the aramid nanofiber dispersion to obtain a coated film, subjecting the coated film to annealing, immersion in a mixed solution, washing and drying, then performing magnetron sputtering in a magnetron sputtering device to deposit a rigid coating, thereby obtaining the composite film.

The inventors found in the actual experimental process that there is mutual entanglement between the porous film and the aramid nanofiber layer, and between the aramid nanofiber layer and the rigid coating in the composite film. During the annealing process, a combined effect of the solvent evaporation of the aramid nanofiber (ANF) and the partial melting of polyolefin chains in the porous film promotes the polyolefin molecular chains to quickly diffuse to adjacent surfaces of the ANF and get entangled with each other, thereby forming a strong interfacial interlocking between the ANF and the polyolefin base material. In addition, the magnetron sputtered particles are bonded to the ANF with a high specific surface area, through the nano-confinement effect (physical adsorption) and the formation of coordination structures with the nitrogen (N) and oxygen (O) elements on the ANF, further improving the stability of the coating. At the same time, in the present disclosure, the aramid nanofiber layer (with an elastic modulus of 40-60 GPa) is an intermediate layer between the rigid coating (with an elastic modulus of >50 GPa) and the flexible porous film (with an elastic modulus of <30 GPa) and thus form a gradient modulus interface layer and reduce the stress concentration of the interfaces, effectively solving the delamination issue between the rigid coating and the flexible porous film under the dynamic mechanical behaviors, and significantly improving the interfacial stability of the material.

The inventors found in the actual research process that the pore size distribution and porosity characteristics of the porous film of the composite film finally prepared are synergistically regulated by an annealing temperature and an input power of magnetron sputtering. Studies have shown that within an appropriate temperature range, the thermal activation effect can promote the migration and rearrangement of the polyolefin chains, and significantly enhance the strength of the interfacial bonding by forming a topological entanglement structure with the aramid nanofibers. In addition, increasing the input power of magnetron sputtering can enhance the bonding of rigid nanoparticles and aramid nanofibers.

However, when the process parameters exceed the critical thresholds, the matrix melting phenomenon caused by overheating will destroy the integrity of the porous structure.

Preferably, in step S1, the preparation method of the composite film satisfies at least one of the following (1)-(4):
(1) the aramid fiber is a para-aramid fiber or a meta-aramid fiber;
(2) a mass-to-volume ratio of the aramid fiber, the alkaline solution and the organic solvent is (0.1-2) g:(3-20) mL: 100 mL;
(3) the alkaline solution is a mixture of an alkali and a proton donor, and a mass-to-volume ratio of the alkali to the proton donor is (0.1-10) g:(2-20) mL; and
(4) the organic solvent is dimethyl sulfoxide and/or dimethyl fumarate.

In some embodiments, the alkali is sodium hydroxide and/or potassium hydroxide; the proton donor is at least one selected from the group consisting of water, ethanol, isopropanol, ethylene glycol, propylene glycol and butanediol.

In some embodiments, the meta-aramid fiber is a conventional meta-aramid fiber in the art, such as Nomex® (DuPont de Nemours, Inc., America), Conex® (Teijin Frontier Co., LTD., Japan) and New Star® (Hangzhou Taihe New Materials Co., Ltd., China); the para-aramid fiber is a conventional para-aramid fiber in the art, such as Kevlar® (DuPont de Nemours, Inc.), Twaron® (Teijin Frontier Co., LTD., Japan), Taparan® (Hangzhou Taihe New Materials Co., Ltd., China);

In some embodiments, the aramid fiber is a Kevlar fiber, purchased from the DuPont de Nemours, Inc., America.

In some embodiments, the alkali is potassium hydroxide.

In some embodiments, in step S2, the preparation method of the composite film satisfies at least one of the following (5)-(9):
(5) an annealing temperature is 100-130° C., and an annealing time is 10-20 min;
(6) the mixed solution is a mixture of dimethyl sulfoxide and isopropanol, and a volume ratio of the dimethyl sulfoxide to the isopropanol is (0.1-0.5):1;
(7) an immersion time is 5-30 min;
(8) a vacuum degree of the magnetron sputtering is 10⁻⁴ Pa, an input power of the magnetron sputtering is 5-200 W, and a magnetron sputtering time is 20-1500 s;
(9) a target material of the magnetron sputtering is at least one selected from the group consisting of copper, aluminum, platinum, gold, silver, titanium, molybdenum, silicon, aluminum oxide, indium tin oxide, silicon oxide and titanium oxide.

In some embodiments, the annealing temperature is 120-130° C.

In some embodiments, the immersion time is 10-20 min.

In some embodiments, the input power of the magnetron sputtering is 25-100 W, and the magnetron sputtering time is 50-300 s.

It should be noted that the composite film described in the present disclosure can also be referred to as a composite coating. In the present disclosure, the terms “film” and “coating” can be used interchangeably, the “film” emphasizes the structural integrity and/or the functional integrity, and the “coating” emphasizes surface adhesion. The composite film or coating can be used alone (i.e., the composite film or coating is not required to be combined with other substances; for example, it can be directly used as a conductive film). The composite film can also be used in combination with other substances, such as being covered on a surface of other substances (or being placed between two substances). It should be noted that there is no restriction on a direction of the composite film when used, even when used in combination with other substances.

The present disclosure provides a use of the composite film in preparation of a flexible electronic device.

The present disclosure provides a flexible electronic device comprising the composite film, wherein the composite film is configured as a conductive film; or the composite film is connected to an electronic component by a conductive adhesive.

In some embodiments, the conductive film is a flexible conductive film.

In some embodiments, the flexible electronic device is selected from a wearable sensor, an electronic skin, a flexible display screen, and a flexible solar cell. Non-limiting examples of the wearable sensor and/or the electronic skin include a medical sensor, an electrode-type touch sensor, a sleeve sensor, etc.

In some embodiments, the composite film is connected to an electronic component (e.g., a conductive tab) by a conductive adhesive (e.g., silver paste or an anisotropic conductive adhesive) to achieve signal transmission with an external device.

In some embodiments, the composite film can be affixed (e.g., directly applied) to a biological surface (e.g., a skin surface) for monitoring a bioelectric signal (e.g., electrocardiogram, an electromyography signal). That is, the composite film can be used as a medical sensor or an electronic skin.

In some embodiments, the composite film can also be used as an electrode-type touch sensor, wirelessly connected to an external device (e.g., connected by Bluetooth) to achieve gesture control. For example, the composite film is used as a sleeve sensor to control a computer game or a virtual reality device, with high response sensitivity and no delay.

In some embodiments, the composite film is configured as a flexible conductive film and is directly applied in a flexible electronic device. For example, the composite film is used as a transparent conductive layer of a flexible solar cell.

Compared with the prior art, the present disclosure has the following beneficial effects. The preparation of the composite film in the present disclosure has simple operation steps, and the process equipment used brings a possibility of achieving large-scale and continuous production. In the present disclosure, the deprotonation-reprotonation process of the aramid fiber is utilized to establish the entanglement, along with the nano-confinement effect, between the aramid nanofiber layer and the flexible porous film, thereby addressing the issue that the addition of an adhesive or a surface treatment is required to achieve the interfacial bonding between the aramid nanofiber and the porous film in the prior art. In the composite film of the present disclosure, the aramid nanofiber layer is an intermediate layer between the rigid coating and the flexible porous film and provides a mechanical transition therebetween and thus regulate interfaces thereof, so that a stable interface structure is achieved between the flexible porous film and the rigid coating, thereby effectively solving the delamination issue between the rigid coating and the flexible porous film.

### BRIEF DESCRIPTION OF DRAWINGS

The sole FIGURE is a scanning electron microscopy (SEM) image of a composite film prepared in Example 1.

### DETAILED DESCRIPTION

For better illustrations of the objective, technical solutions and advantages of the present disclosure, the present disclosure will be further described below in conjunction with accompanying drawings and specific embodiments. The embodiments are intended to understand the contents of the present disclosure in detail, rather than to limit the present disclosure. Any other embodiment obtained by those skilled in the art without creative work falls within the scope of protection of the present disclosure. Unless otherwise specified, experimental reagents and instruments used in the examples and comparative examples of the present disclosure are all ordinary ones, which are commonly used and commercially available. In the examples and comparative examples, experimental methods used are all conventional ones, unless otherwise specified. Unless otherwise specified, raw materials used in parallel experiments are in the same batch.

### Example 1

A composite film was provided, comprising a porous film, an aramid nanofiber layer and a rigid coating arranged in sequence; the porous film was formed by a polyolefin nanofiber and had a porous structure. Specifically, the porous film was a polyethylene porous film, with an original pore size of 40 nm, an original porosity of 55±5%, and an original thickness of 2.5±0.5 μm (purchased from Guangzhou Guna Technology Co., Ltd.).

A preparation method of the composite film included the following steps:
(1) evenly mixing a Kevlar fiber, an alkaline solution, and an organic solvent (dimethyl sulfoxide) to obtain an aramid nanofiber dispersion;
Preparation of the alkaline solution: the alkaline solution was a mixed solution of KOH and a proton donor; the KOH and the proton donor were evenly mixed at a temperature of 60° C. for 5 minutes to obtain the alkaline solution; a mass-to-volume ratio of the KOH to the proton donor was 0.3 g:3 mL; and the proton donor was ethylene glycol;
A mass-to-volume ratio of the Kevlar fiber, the alkaline solution and the dimethyl sulfoxide was 0.5 g: 3 mL: 100 mL; the Kevlar fiber, the alkaline solution and the dimethyl sulfoxide were stirred and mixed uniformly in a stirring device (a magnetic stirrer), a stirring temperature was 60° C., and a reaction time was 10 minutes;
(2) (In some embodiments, the coating and/or annealing and/or immersion were performed in a nitrogen atmosphere) coating a surface of the porous film with the aramid nanofiber dispersion to obtain a coated film, subjecting the coated film to annealing at 130° C. for 10 minutes, immersion in a mixed solution for 10 minutes, washing and drying, and performing magnetron sputtering in a magnetron sputtering device to deposit a rigid coating, thereby obtaining the composite film; wherein the mixed solution was a mixture of dimethyl sulfoxide and isopropanol, and a volume ratio of the dimethyl sulfoxide to the isopropanol was 0.2:1; in the magnetron sputtering device, a vacuum degree was adjusted to 10⁻⁴ Pa, (in some embodiments, the magnetron sputtering was carried out in an inert gas atmosphere, such as in an argon atmosphere), a target material was copper, an input power of the magnetron sputtering was 25 W, and a magnetron sputtering time was 300 s.

### Example 2

The only difference between Example 2 and Example 1 was that the volume ratio of the mixed solution in Step (2) was different. Specifically, in Example 2, the mixed solution was a mixture of dimethyl sulfoxide and isopropanol, and the volume ratio of the dimethyl sulfoxide to the isopropanol was 0.5:1.

### Example 3

The only difference between Example 3 and Example 1 was that the input power of the magnetron sputtering and the magnetron sputtering time were different. Specifically, in Example 3, the input power of the magnetron sputtering was 100 W and the magnetron sputtering time was 75 s.

### Example 4

The only difference between Example 4 and Example 1 was that the input power of the magnetron sputtering and the magnetron sputtering time were different. Specifically, in Example 4, the input power of the magnetron sputtering was 10 W and the magnetron sputtering time was 750 s.

### Example 5

The only difference between Example 5 and Example 1 was that the input power of the magnetron sputtering and the magnetron sputtering time were different. Specifically, in Example 5, the input power of the magnetron sputtering was 200 W and the magnetron sputtering time was 37.5 s.

### Example 6

The only difference between Example 6 and Example 1 was that the immersion time was different. Specifically, in Example 6, the immersion time in was 20 min.

### Example 7

The only difference between Example 7 and Example 1 was that the immersion time was different. Specifically, in Example 7, the immersion time was 5 min.

### Example 8

The only difference between Example 8 and Example 1 was that the annealing temperature and the annealing time were different. Specifically, in Example 8, the annealing was performed at 100° C. for 20 minutes.

### Example 9

The only difference between Example 9 and Example 1 was that the original thickness of the porous film was different. In Example 9, the porous film was a polyethylene porous membrane with an original pore size of 35 nm, an original porosity of 45±5%, and an origianl thickness of 5±0.5 μm (purchased from Guangzhou Guna Technology Co., Ltd.).

### Example 10

The only difference between Example 10 and Example 1 was that the components of the alkaline solution were different. Specifically, in Example 10, the alkaline solution was a mixture of KOH and water.

### Example 11

The only difference between Example 11 and Example 1 was that the target material is different. Specifically, in Example 11 the target material was silver.

### Example 12

The only difference between Example 12 and Example 1 was that the aramid fiber was different. Specifically, in Example 12, the aramid fiber was a Nomex fiber, purchased from DuPont de Nemours, Inc., America.

### Example 13

The only difference between Example 13 and Example 1 was that the mass-to-volume ratio of the aramid fiber, the alkaline solution, and the organic solvent was different. Specifically, in Example 13, the mass-to-volume ratio of the aramid fiber, the alkaline solution, and the organic solvent was 2 g: 15 mL: 100 mL.

### Example 14

The only difference between Example 14 and Example 1 was that the mass-to-volume ratio of the alkali to the proton donor in the alkaline solution was different. Specifically, in Example 14, the mass-to-volume ratio of the alkali to the proton donor in the alkaline solution was 5 g: 15 mL.

### Example 15

The only difference between Example 15 and Example 1 was that parameters of the aramid nanofiber layer were different. The parameters of the aramid nanofiber layer were adjusted by changing the amount of the aramid nanofiber dispersion added during the coating process.

### Example 16

The only difference between Example 16 and Example 1 was that the thickness of the rigid coating was different. The thickness of the rigid coating was adjusted by changing the magnetron sputtering time.

### Comparative Example 1

The only difference between Comparative Example 1 and Example 1 was that no annealing was performed before immersion in the preparation process. Specifically, in Comparative Example 1, a composite film and a preparation method thereof were provided as following.

A composite film was provided, comprising a porous film, an aramid nanofiber layer and a rigid coating arranged in sequence.

A preparation method of the composite film included the following steps:
(1) evenly mixing a Kevlar fiber, an alkaline solution, and an organic solvent (dimethyl sulfoxide) to obtain an aramid nanofiber dispersion;
Preparation of the alkaline solution: the alkaline solution was a mixed solution of KOH and a proton donor; the KOH and the proton donor were evenly mixed at a temperature of 60° C. for 5 minutes to obtain the alkaline solution; a mass-to-volume ratio of the KOH to the proton donor was 0.3 g:3 mL; and the proton donor was ethylene glycol;
A mass-to-volume ratio of the Kevlar fiber, the alkaline solution and the dimethyl sulfoxide was 0.5 g:3 mL:100 mL; the Kevlar fiber, the alkaline solution and the dimethyl sulfoxide were stirred and mixed uniformly in a stirring device (a magnetic stirrer), a stirring temperature was 60° C., and a reaction time was 10 minutes;
(2) under the protection of nitrogen, coating a surface of the porous film with the aramid nanofiber dispersion to obtain a coated film, subjecting the coated film to immersion in a mixed solution for 10 minutes, washing and drying, then performing magnetron sputtering in a magnetron sputtering device to deposit a rigid coating, thereby obtaining the composite film; the mixed solution was a mixture of dimethyl sulfoxide and isopropanol, and a volume ratio of the dimethyl sulfoxide to the isopropanol was 0.2:1; the porous film was a polyethylene porous film, with an original pore size of 40 nm, an original porosity of 55±5%, and an original thickness of 2.5±0.5 μm (purchased from Guangzhou Guna Technology Co., Ltd.); in the magnetron sputtering device, a vacuum degree was adjusted to 10⁻⁴ Pa, the magnetron sputtering was carried out in an atmosphere of Argon, a target material was copper, an input power of the magnetron sputtering was 25 W, and a magnetron sputtering time was 30 0s.

### Comparative Example 2

The only difference between Comparative Example 2 and Example 1 was that the volume ratio of the mixed solution in Step (2) was different. Specifically, in Comparative Example 2, the mixed solution was a mixture of dimethyl sulfoxide and isopropanol, and the volume ratio of the dimethyl sulfoxide to the isopropanol was 0.05:1.

### Comparative Example 3

The only difference between Comparative Example 3 and Example 1 was that the mixed solution in Step (2) was different. Specifically, in Comparative Example 3, the mixed solution was a mixture of water and ethanol, and the volume ratio of water to ethanol was 0.2:1.

### Comparative Example 4

The only difference between Comparative Example 4 and Example 1 was that the input power of the magnetron sputtering and the magnetron sputtering time were different. Specifically, in Comparative Example 4, the input power of the magnetron sputtering was 250 W and the magnetron sputtering time was 30 s.

### Comparative Example 5

The only difference between Comparative Example 5 and Example 1 was that the annealing temperature and the annealing time were different. Specifically, in Comparative Example 5, the annealing was performed at 80° C. for 20 minutes.

### Comparative Example 6

The only difference between Comparative Example 6 and Example 1 was that no immersion was performed in the preparation process. Specifically, in Comparative Example 6, a composite film and a preparation method thereof were provided as following.

A composite film was provided, comprising a porous film, an aramid nanofiber layer and a rigid coating arranged in sequence.

A preparation method of the composite film included the following steps:
(1) evenly mixing a Kevlar fiber, an alkaline solution, and an organic solvent (dimethyl sulfoxide) to obtain an aramid nanofiber dispersion;
Preparation of the alkaline solution: the alkaline solution was a mixed solution of KOH and a proton donor; the KOH and the proton donor were evenly mixed at a temperature of 60° C. for 5 minutes to obtain the alkaline solution; a mass-to-volume ratio of the KOH to the proton donor was 0.3 g: 3 mL; and the proton donor was ethylene glycol;
A mass-to-volume ratio of the Kevlar fiber, the alkaline solution and the dimethyl sulfoxide was 0.5 g: 3 mL: 100 mL; the Kevlar fiber, the alkaline solution and the dimethyl sulfoxide were stirred and mixed uniformly in a stirring device (a magnetic stirrer), a stirring temperature was 60° C., and a reaction time was 10 minutes;
(2) under the protection of nitrogen, coating a surface of the porous film with the aramid nanofiber dispersion to obtain a coated film, subjecting the coated film to annealing at 130° C. for 10 minutes, washing and drying, and then performing magnetron sputtering in a magnetron sputtering device to deposit a rigid coating, thereby obtaining the composite film; the porous film was a polyethylene porous film, with an original pore size of 40 nm, an original porosity of 55±5%, and an original thickness of 2.5±0.5 μm (purchased from Guangzhou Guna Technology Co., Ltd.); in the magnetron sputtering device, a vacuum degree was adjusted to 10⁻⁴ Pa, the magnetron sputtering was carried out in an atmosphere of Argon, a target material was copper, an input power of the magnetron sputtering was 25 W, and a magnetron sputtering time was 300 s.

### Comparative Example 7

The only difference between Comparative Example 7 and Example 1 was that an aramid nanofiber layer was not contained in the composite film. Specifically, in Comparative Example 7, the preparation method of the composite film included the following steps: placing a porous film in a magnetron sputtering device, adjusting a vacuum degree to 10⁻⁴ Pa, and performing magnetron sputtering in an argon atmosphere to deposit a rigid coating, thereby obtain the composite film; wherein a target material was copper, an input power of the magnetron sputtering was 25 W, and a magnetron sputtering time was 300 s; the porous film was a polyethylene porous film, with an original pore size of 40 nm, an original porosity of 55±5%, and an original thickness of 2.5±0.5 μm (purchased from Guangzhou Guna Technology Co., Ltd.).

### Comparative Example 8

The only difference between Comparative Example 8 and Example 1 was that an aramid nanofiber layer was not contained in the composite film. Specifically, in Comparative Example 8, the preparation method of the composite film included the following steps: placing a porous film in a magnetron sputtering device, adjusting a vacuum degree to 10⁻⁴ Pa, and performing magnetron sputtering in an argon atmosphere to deposit a rigid coating, thereby obtain the composite film; wherein a target material was copper, an input power of the magnetron sputtering was 100 W, and a magnetron sputtering time was 75 s; the porous film was a polyethylene porous film, with an original pore size of 40 nm, an original porosity of 55±5%, and an original thickness of 2.5±0.5 μm (purchased from Guangzhou Guna Technology Co., Ltd.).

### Comparative Example 9

The difference between Comparative Example 9 and Example 1 was that parameters of the aramid nanofiber layer were different. The parameters of the aramid nanofiber layer were adjusted by changing the amount of the aramid nanofiber dispersion added during the coating process.

### Comparative Example 10

The difference between Comparative Example 10 and Example 1 was that the thickness of the rigid coating was different. The thickness of the rigid coating was adjusted by changing the magnetron sputtering time.

### Comparative Example 11

The difference between Comparative Example 11 and Example 1 was that the thickness of the rigid coating was different. The thickness of the rigid coating was adjusted by changing the magnetron sputtering time.

Structural parameters of a porous film, an aramid nanofiber layer, and a rigid coating of a composite film prepared in each of the Examples 1-16 and Comparative Examples 1-11 in the present disclosure were respectively shown in Table 1 below, wherein a fiber diameter and a pore size were obtained by scanning electron microscopy (SEM); a porosity was determined by a simple weight method and calculated based on a thickness and a density of a corresponding material layer, and the fiber diameter and the pore size were both averaged.

The thickness was measured by a Mahr thickness gauge.

Table 1 Structural parameter of the porous film, the aramid nanofiber layer and the rigid coating of the composite films prepared in Examples 1-16 (E1-E16) and Comparative Examples 1-11

(CE1-CE11)

| | Porous film | | | | Aramid nanofiber layer | | | | Rigid coating | |
|---|---|---|---|---|---|---|---|---|---|---|
| Item | Thickness, | Pore | Porosity, | Diameter, | Thickness, | Pore | Porosity, | Diameter, | Thickness, | Coating |
| Item | um | size, nm | % | nm | um | size, nm | % | nm | um | type |
| E1 | 2.5 | 35 | 45 ± 3 | 50 | 0.2 | 50 | 35 ± 2 | 20 | 0.08 | copper |
| E2 | 2.5 | 35 | 45 ± 3 | 50 | 0.2 | 40 | 32 ± 2 | 20 | 0.08 | copper |
| E3 | 2.5 | 32 | 41 ± 3 | 50 | 0.2 | 50 | 35 ± 2 | 20 | 0.08 | copper |
| E4 | 2.5 | 43 | 48 ± 3 | 40 | 0.2 | 50 | 35 ± 2 | 20 | 0.08 | copper |
| E5 | 2.5 | 20 | 30 ± 3 | 60 | 0.2 | 50 | 35 ± 2 | 20 | 0.08 | copper |
| E6 | 2.5 | 35 | 45 ± 3 | 50 | 0.2 | 45 | 35 ± 2 | 20 | 0.08 | copper |
| E7 | 2.5 | 35 | 45 ± 3 | 50 | 0.2 | 20 | 15 ± 2 | 20 | 0.08 | copper |
| E8 | 2.5 | 48 | 53 ± 3 | 30 | 0.2 | 50 | 35 ± 2 | 20 | 0.08 | copper |
| E9 | 5 | 32 | 42 ± 3 | 50 | 0.2 | 50 | 35 ± 2 | 20 | 0.08 | copper |
| E10 | 2.5 | 35 | 45 ± 3 | 50 | 0.2 | 50 | 35 ± 2 | 25 | 0.08 | copper |
| E11 | 2.5 | 35 | 45 ± 3 | 50 | 0.2 | 50 | 35 ± 2 | 20 | 0.08 | silver |
| E12 | 2.5 | 35 | 45 ± 3 | 50 | 0.2 | 50 | 35 ± 2 | 20 | 0.08 | copper |
| E13 | 2.5 | 35 | 45 ± 3 | 50 | 0.2 | 50 | 35 ± 2 | 25 | 0.08 | copper |
| E14 | 2.5 | 35 | 45 ± 3 | 50 | 0.2 | 50 | 35 ± 2 | 28 | 0.08 | copper |
| E15 | 2.5 | 35 | 45 ± 3 | 50 | 1 | 25 | 15 ± 2 | 20 | 0.08 | copper |
| E16 | 2.5 | 35 | 45 ± 3 | 50 | 0.2 | 50 | 35 ± 2 | 20 | 0.3 | copper |
| CE1 | 2.5 | 35 | 45 ± 3 | 50 | 0.2 | 200 | 40 ± 2 | 20 | 0.08 | copper |
| CE2 | 2.5 | 35 | 45 ± 3 | 50 | 0.2 | 120 | 30 ± 2 | 20 | 0.08 | copper |
| CE3 | 2.5 | 35 | 45 ± 3 | 50 | 0.2 | 10 | 15 ± 2 | 20 | 0.08 | copper |
| CE4 | — | — | — | — | — | — | — | — | — | — |
| CE5 | 2.5 | 45 | 60 ± 5 | 25 | 0.2 | 50 | 35 ± 2 | 20 | 0.08 | copper |
| CE6 | 2.5 | 35 | 45 ± 3 | 50 | 0.2 | 10 | 15 ± 2 | 20 | 0.08 | copper |
| CE7 | 2.5 | 32 | 35 ± 3 | 60 | — | — | — | — | 0.08 | copper |
| CE8 | 2.5 | 10 | 10 ± 2 | 100 | — | — | — | — | 0.08 | copper |
| CE9 | 2.5 | 35 | 45 ± 3 | 50 | 0.03 | 100 | 50 ± 3 | 20 | 0.08 | copper |
| CE10 | 2.5 | 35 | 45 ± 3 | 50 | 0.2 | 50 | 35 ± 2 | 20 | 0.005 | copper |
| CE11 | 2.5 | 35 | 45 ± 3 | 50 | 0.2 | 50 | 35 ± 2 | 20 | 1.5 | copper |

### Performance Testing

(1) The composite films prepared in the Examples 1-16 and Comparative Examples 1-11 were subjected to peel strength testing. A tensile testing machine was adopted for testing, and the peel strength testing included the following steps: taking a testing sample with a dimension of 15×100 mm, attaching a porous film of the testing sample to a stainless steel plate with a double-sided tape, then evenly attaching another adhesive tape on a rigid coating of the testing sample, using a 1 kg standard pressure roller to roll back and forth on the testing sample for 3 times; then mounting the pressed sample to the tensile testing machine and performing a 180° peel test at a speed of 100 mm/min, and recording a maximum value as a result.
(2) The composite films prepared in the Examples 1-16 and Comparative Examples 1-11 were subjected to resistance testing. A flexible electronic tester was used for testing, and the resistance testing included the following steps: taking a testing sample with a dimension of 10×30 mm, fixing two ends of the testing sample to two sides of a folding fixture of the flexible electronic tester with an adhesive tape, respectively; setting folding parameters of the flexible electronic tester as follows: initial angle, 0°; folding angle, 180°; folding rate, 40°/s; number of folds, 10,000 folds and 100,000 folds; and folding radius, 0.3 mm; after folding, measuring the resistance of the testing sample with a milliohm meter, and recording a maximum value as a result.

Testing results were shown in Table 2.

TABLE 2
Results of performance testing for the composite films prepared in
Examples 1-16 and Comparative Examples 1-11

| | Peel | | Resistance | Resistance |
|---|---|---|---|---|
| | strength, | Initial | after 10,000 | after 100,000 |
| Item | kN/m | resistance, Ω | folds, Ω | folds, Ω |
| Example 1 | 1.32 | 1.2 | 1.2 | 2.6 |
| Example 2 | 1.24 | 1.4 | 1.4 | 2.8 |
| Example 3 | 1.27 | 1.0 | 1.1 | 2.2 |
| Example 4 | 0.88 | 1.3 | 1.7 | 4.3 |
| Example 5 | 0.82 | 1.7 | 2.3 | 5.4 |
| Example 6 | 1.11 | 1.3 | 1.4 | 2.1 |
| Example 7 | 0.83 | 1.5 | 2.1 | 6.3 |
| Example 8 | 0.96 | 1.1 | 1.3 | 7.3 |
| Example 9 | 0.86 | 1.6 | 2.0 | 5.4 |
| Example 10 | 1.21 | 1.4 | 1.4 | 2.7 |
| Example 11 | 1.28 | 0.4 | 0.5 | 1.1 |
| Example 12 | 1.23 | 1.3 | 1.3 | 2.5 |
| Example 13 | 1.22 | 1.1 | 1.2 | 2.3 |
| Example 14 | 1.17 | 1.3 | 1.3 | 2.4 |
| Example 15 | 1.15 | 1.0 | 1.1 | 2.6 |
| Example 16 | 0.97 | 0.2 | 0.2 | 0.4 |
| Comparative | 0.13 | 2.8 | >1000 | >1000 |
| Example 1 | | | | |
| Comparative | 0.43 | 1.8 | 67 | 189 |
| Example 2 | | | | |
| Comparative | 0.32 | 3.6 | 112 | 349 |
| Example 3 | | | | |
| Comparative | — | — | — | — |
| Example 4 | | | | |
| Comparative | 0.24 | 2.7 | 433 | >1000 |
| Example 5 | | | | |
| Comparative | 0.31 | 4.8 | 240 | >1000 |
| Example 6 | | | | |
| Comparative | 0.29 | 1.9 | 767 | >1000 |
| Example 7 | | | | |
| Comparative | 0.22 | 6.3 | >1000 | >1000 |
| Example 8 | | | | |
| Comparative | 0.53 | 5.9 | 47 | 127 |
| Example 9 | | | | |
| Comparative | 0.95 | 230 | 255 | 367 |
| Example 10 | | | | |
| Comparative | 0.68 | <0.1 | >1000 | >1000 |
| Example 11 | | | | |

As can be seen from the above table, the composite film provided in the present disclosure can effectively improve the interfacial bonding between the rigid coating and the flexible film, thereby solving the delamination issue during the dynamic deformation process and meeting the application requirements of flexible electronic devices. The sole FIGURE is a scanning electron microscopy (SEM) image of a composite film prepared in Example 1, wherein metal particles are coated on aramid nanofibers to form a stable deposition, achieving a fibrous conductive network structure. In this way, the material has a stable gradient mechanical architecture and thus maintains excellent conductive properties under extreme dynamic mechanical behaviors. Based on the excellent performance of the composite film in terms of peel strength, resistance and bending resistance, the composite film is suitable for serving as a conductive film in a flexible electronic device; particularly, the composite film is suitable for use in scenes that require long-term attachments or frequent bending, for example, flexible electronic devices, such as a wearable sensor, an electronic skin, a medical sensor, an electrode-type touch sensor, a sleeve sensor and so on.

In addition, as the power of magnetron sputtering was too large, kinetic energy of the high-energy particles was converted into heat energy, resulting in cracks of the composite film prepared in Comparative Example 4. Therefore, no subsequent testing was performed.

Finally, it should be noted that the above embodiments are only intended to illustrate the technical solutions of the present disclosure, rather than to limit the protection scope of the present disclosure. Although the present disclosure has been described in detail with reference to the preferred embodiments, those skilled in the art shall understand that the technical solutions of the present disclosure may be modified or equivalently substituted, without departing from the essence and scope of the technical solution of the present disclosure.

1. A composite film, comprising a porous film, an aramid nanofiber layer and a rigid coating arranged in sequence; wherein the porous film is formed by a polyolefin nanofiber and has a porous structure; the aramid nanofiber layer is formed by an aramid nanofiber and has a porous structure; and the rigid coating is formed by at least one selected from the group consisting of copper, aluminum, platinum, gold, silver, titanium, molybdenum, silicon, aluminum oxide, indium tin oxide, silicon oxide and titanium oxide.

2. The composite film according to claim 1, wherein the porous film has a thickness of 0.1-10 μm, a pore size of 20-80 nm and a porosity of 30-60%; a diameter of the polyolefin nanofiber is 30-60 nm; and/or
the aramid nanofiber layer has a thickness of ≥0.05 μm, a pore size of 20-80 nm and a porosity of 10-50%; a diameter of the aramid nanofiber is 10-50 nm; and/or
a thickness of the rigid coating is 0.01-1 μm.

3. The composite film according to claim 2, wherein the pore size of the porous film is 30-40 nm, and the porosity of the porous film is 35-50%; the diameter of the polyolefin nanofiber is 45-55 nm.

4. The composite film according to claim 2, wherein the pore size of the aramid nanofiber layer is 30-50 nm, and the porosity of the aramid nanofiber layer is 30-40%; the diameter of the aramid nanofiber is 20-30 nm.

5. A preparation method of the composite film according to claim 1, comprising the following steps:
S1, evenly mixing an aramid fiber, an alkaline solution and an organic solvent to obtain an aramid nanofiber dispersion;
S2, coating a surface of the porous film with the aramid nanofiber dispersion to obtain a coated film, subjecting the coated film to annealing, immersion in a mixed solution, washing and drying, then performing magnetron sputtering in a magnetron sputtering device to deposit a rigid coating, thereby obtaining the composite film.

6. The preparation method of the composite film according to claim 5, wherein in step S1, the preparation method of the composite film satisfies at least one of the following (1)-(4):
(1) the aramid fiber is a para-aramid fiber or a meta-aramid fiber;
(2) a mass-to-volume ratio of the aramid fiber, the alkaline solution and the organic solvent is (0.1-2) g:(3-20) mL: 100 mL;
(3) the alkaline solution is a mixture of an alkali and a proton donor, and a mass-to-volume ratio of the alkali to the proton donor is (0.1-10) g:(2-20) mL; and
(4) the organic solvent is dimethyl sulfoxide and/or dimethyl fumarate.

7. The preparation method of the composite film according to claim 6, wherein the alkali is sodium hydroxide and/or potassium hydroxide; the proton donor is at least one selected from the group consisting of water, ethanol, isopropanol, ethylene glycol, propylene glycol and butanediol.

8. The preparation method of the composite film according to claim 5, wherein in step S2, the preparation method of the composite film satisfies at least one of the following (5)-(9):
(5) an annealing temperature is 100-130° C., and an annealing time is 10-20 min;
(6) the mixed solution is a mixture of dimethyl sulfoxide and isopropanol, and a volume ratio of the dimethyl sulfoxide to the isopropanol is (0.1-0.5):1;
(7) an immersion time is 5-30 min;
(8) a vacuum degree of the magnetron sputtering is 10⁻⁴ Pa, an input power of the magnetron sputtering is 5-200 W, and a magnetron sputtering time is 20-1500 s; and
(9) a target material of the magnetron sputtering is at least one selected from the group consisting of copper, aluminum, platinum, gold, silver, titanium, molybdenum, silicon, aluminum oxide, indium tin oxide, silicon oxide and titanium oxide.

9. The preparation method of the composite film according to claim 8, wherein the immersion time is 10-20 min; and/or the input power of the magnetron sputtering is 25-100 W, and the magnetron sputtering time is 50-300 s.

10. The preparation method of the composite film according to claim 5, wherein the porous film has a thickness of 0.1-10 μm, a pore size of 20-80 nm and a porosity of 30-60%; a diameter of the polyolefin nanofiber is 30-60 nm; and/or
the aramid nanofiber layer has a thickness of ≥0.05 μm, a pore size of 20-80 nm and a porosity of 10-50%; a diameter of the aramid nanofiber is 10-50 nm; and/or
a thickness of the rigid coating is 0.01-1 μm.

11. The preparation method of the composite film according to claim 10, wherein in step S1, the preparation method of the composite film satisfies at least one of the following (1)-(4):
(1) the aramid fiber is a para-aramid fiber or a meta-aramid fiber;
(2) a mass-to-volume ratio of the aramid fiber, the alkaline solution and the organic solvent is (0.1-2) g:(3-20) mL: 100 mL;
(3) the alkaline solution is a mixture of an alkali and a proton donor, and a mass-to-volume ratio of the alkali to the proton donor is (0.1-10) g:(2-20) mL; and
(4) the organic solvent is dimethyl sulfoxide and/or dimethyl fumarate.

12. The preparation method of the composite film according to claim 11, wherein the alkali is sodium hydroxide and/or potassium hydroxide; the proton donor is at least one selected from the group consisting of water, ethanol, isopropanol, ethylene glycol, propylene glycol and butanediol.

13. The preparation method of the composite film according to claim 10, wherein in step S2, the preparation method of the composite film satisfies at least one of the following (5)-(9):
(5) an annealing temperature is 100-130° C., and an annealing time is 10-20 min;
(6) the mixed solution is a mixture of dimethyl sulfoxide and isopropanol, and a volume ratio of the dimethyl sulfoxide to the isopropanol is (0.1-0.5):1;
(7) an immersion time is 5-30 min;
(8) a vacuum degree of the magnetron sputtering is 10⁻⁴ Pa, an input power of the magnetron sputtering is 5-200 W, and a magnetron sputtering time is 20-1500 s; and
(9) a target material of the magnetron sputtering is at least one selected from the group consisting of copper, aluminum, platinum, gold, silver, titanium, molybdenum, silicon, aluminum oxide, indium tin oxide, silicon oxide and titanium oxide.

14. The preparation method of the composite film according to claim 13, wherein the immersion time is 10-20 min; and/or the input power of the magnetron sputtering is 25-100 W, and the magnetron sputtering time is 50-300 s.

15. The preparation method of the composite film according to claim 10, wherein the pore size of the porous film is 30-40 nm, and the porosity of the porous film is 35-50%; the diameter of the polyolefin nanofiber is 45-55 nm.

16. The preparation method of the composite film according to claim 10, wherein the pore size of the aramid nanofiber layer is 30-50 nm, and the porosity of the aramid nanofiber layer is 30-40%; the diameter of the aramid nanofiber is 20-30 nm.

17. A flexible electronic device, comprising the composite film according to claim 1,
wherein the composite film is configured as a conductive film; or the composite film is connected to an electronic component by a conductive adhesive.

18. The flexible electronic device according to claim 17, wherein the porous film has a thickness of 0.1-10 μm, a pore size of 20-80 nm and a porosity of 30-60%; a diameter of the polyolefin nanofiber is 30-60 nm; and/or
the aramid nanofiber layer has a thickness of ≥0.05 μm, a pore size of 20-80 nm and a porosity of 10-50%; a diameter of the aramid nanofiber is 10-50 nm; and/or
a thickness of the rigid coating is 0.01-1 μm.

19. The flexible electronic device according to claim 18, wherein the pore size of the porous film is 30-40 nm, and the porosity of the porous film is 35-50%; the diameter of the polyolefin nanofiber is 45-55 nm.

20. The flexible electronic device according to claim 18, wherein the pore size of the aramid nanofiber layer is 30-50 nm, and the porosity of the aramid nanofiber layer is 30-40%; the diameter of the aramid nanofiber is 20-30 nm.
